(19) United States
(12) Patent Application Publication
(10) Pub. No.: US 2016/0247676 A1
(43) Pub. Date: Aug. 25, 2016

(54) METHOD FOR MANUFACTURING THIN FILM

(71) Applicant: WONIK IPS CO., LTD., Gyeonggi-do (KR)

(72) Inventors: So-Yeon PARK, Bucheon-Si, Gyeonggi-Do (KR); Young-Soo KWON, Yongin-Si, Gyeonggi-Do (KR)

(21) Appl. No.: 15/025,549

(22) PCT Filed: Jun. 18, 2013
(86) PCT No.: PCT/KR2013/005375

§ 371 Date: Mar. 28, 2016

(51) Int. Cl. H01L 21/02

(52) U.S. Cl. CPC H01L 21/02274; H01L 21/02164; H01L 21/02236

(57) ABSTRACT

The present invention includes the steps of: preparing a substrate; preparing a raw material including organic silane having CxHy (here, 1≦x≦9, 4≦y≦20, Y>2X) as a functional group; vaporizing the raw material; loading the substrate to the inside of a chamber; and supplying the vaporized raw material into the chamber. Accordingly, the present invention can manufacture a thin film without degrading the film quality even at low temperatures, and can more reliably and stably manufacture a device for which a low-temperature process is required.

### TECHNICAL FIELD

The present invention relates to a method for manufacturing a thin film, and more particularly to a method for manufacturing a thin film which allows at a low temperature process and is capable of obtaining a thin film having good properties.

### BACKGROUND ART

Various thin films are required for manufacturing electronic devices such as a semiconductor memory on a substrate. That is, when a semiconductor device is manufactured, various thin films are formed on a substrate and the thin films thus formed are patterned by photolithography to form a device structure. There are roughly physical and chemical methods to form thin films. Recently, to form a semiconductor device, chemical vapor deposition (CVD) is usually used where a thin film of a metal, dielectric material or insulator are formed on a substrate by chemical reactions of gases. Also, an atomic layer deposition (ALD) method is used when a micro thin film is required as a device is miniaturized.

Generally, an insulator thin film, in particular a silicon dioxide (SiO₂) thin film which is most widely used in manufacturing a semiconductor device is formed using TEOS (tetraethyl orthosilicate) as a raw material. That is, gaseous TEOS and oxygen are flowed into a process chamber with a substrate loaded and the substrate is heated above a desired temperature to cause reactions on a surface of the substrate, thereby forming a silicon oxide film. To easily form a silicon oxide film with high quality using TEOS, plasma enhanced CVD (PECVD) is used. That is, oxygen and gaseous TEOS is flowed into a process chamber and plasma is generated within the chamber. Then, the introduced gases are activated by plasma in order to grow a silicon oxide film on a substrate. For example, the patent document below discloses the technique of forming a silicon oxide (SiO₂) film from TEOS using the PECVD method.

However, even if a silicon oxide film is manufactured using TEOS and plasma, a temperature range for forming a thin film is limited. That is, since a thin film has poor quality at a temperature below 300 degrees, it is difficult to apply the film to a practical use, and re-reaction of decomposed TEOS is caused at a temperature above 500 degrees so it may adversely affect the resulting thin film after process is completed or particles may be generated.

As an improvement in degree of integration in a semiconductor device is sustainedly required, an effort to increase the degree of integration in horizontal as well as vertical directions has been made. As a method of manufacturing a vertical device, a TSV (through-silicon via) technique is used wherein a plurality of substrates having devices formed thereon is vertically stacked and these substrates are connected via a through-hole. In this TSV process, a via-hole is formed in each substrate, i.e., a silicon wafer, a metal layer is subjected to a peeling and thinning process, and a TSV passivation insulating layer (e.g., silicon oxide film) is formed in the via-hole of the silicon wafer which becomes thin due to the thinning process. By the thinning process, a usual silicon wafer of 750 um thickness has a thinner thickness below 200 um. To handle the thinner silicon wafer thus formed, a glass wafer or another silicon wafer (e.g., handing wafer) is adhered thereto using an adhesive. To cap the metal layer filled in the via-hole of the silicon wafer with the handling wafer adhered, the TSV passivation insulating layer is formed.

However, since adhesives for adhering between wafers cannot withstand a high temperature (e.g., 260 degrees or higher), adhering surfaces between wafers may be lifted or cracks may be generated. Thus, there is a need of an adhesive having high temperature resistance, but the development of a desired adhesive requires very high cost. Thus, a process which allows a low temperature deposition is devoutly needed.

Prior art document: U.S. Pat. No. 5,362,526

### DISCLOSURE OF THE INVENTION

### Technical Problem

The present invention provides a method of manufacturing a thin film.

The present invention provides a method of manufacturing a thin film which allows use of various conditions and apparatuses.

The present invention provides a method of manufacturing a thin film which is capable of easily controlling processes and obtaining a thin film having good breakdown voltage.

### Technical Solution

According to an embodiment, the present invention provides a method of manufacturing a thin film which includes the steps of: providing a substrate; providing a raw material including an organic silane having CxHy (where 1≦x≦9, 4≦y≦20 and y>2x) as a functional group; vaporizing the raw material; loading the substrate into a chamber; and supplying the vaporized raw material to an interior of the chamber.

Further, a method of manufacturing a thin film on a substrate includes the steps of: providing a substrate; providing a raw material including a compound which has a basic structure of SiH₂ and functional groups including carbon and hydrogen linearly coupled to both sides of the basic structure; vaporizing the raw material; loading the substrate into a chamber; and supplying the vaporized raw material to an interior of the chamber.

The functional groups of the raw material may include at least one selected from a methyl group (—CH₃), an ethyl group (—C₂H₅), a benzyl group (—CH₂—C₆H₅) or a phenyl group (—C₆H₅). In particular, the raw material may include C₄H₁₂Si.

In the method described herein, a reaction gas may be supplied to the chamber during or before the vaporized raw material is supplied. The reaction gas is reacted with the raw material to form a thin film and may include an oxygen-containing gas. Also, the vaporized raw material may be supplied together with a carrier gas. The carrier gas preferably includes at least one selected from helium, nitrogen or argon. The thin film formed on the substrate may be an insulation film containing silicon.

Also, the vaporized raw material and the carrier gas may be supplied to an exhaust pipe of the chamber before they are introduced into the chamber. Then, after the flow of vaporized raw material is stabilized, it may be introduced into the chamber. After the vaporized raw material is introduced, plasma is generated in the chamber to promote the formation of a thin film.

A thin film is preferably formed in a temperature range of 80 to 250 degrees. A pressure is preferably in a range 1 to 10 torr during manufacturing a thin film.

When plasma is used in manufacturing a thin film, at least one of high frequency RF power and low frequency RF power may be applied to a gas injection unit provided in the chamber of a thin film-manufacturing apparatus to generate plasma. Power applied to generate plasma may be varied during the formation of a thin film. For example, while a thin film is deposited, the high frequency RF power may be changed to a range of 100 to 1,000 W, or the low frequency RF power may be changed to a range of 100 to 900 W. Further, the total power of high frequency RF power and low frequency RF power may be changed to a range of 100 to 1,300 W.

While a thin film is formed, a flow rate of raw material may also be varied in addition to power of plasma. For example, the flow rate of vaporized raw material may be changed in a range of 50 to 700 sccm while depositing a thin film. Also, a thin film may be deposited by increasing and then decreasing the flow rate while the RF power remains unchanged, or a thin film may be deposited while increasing the RF power and the flow rate.

### Advantageous Effects

A method of manufacturing a thin film according to an embodiment of the present invention can manufacture a thin film having high quality using a new raw material. In particular, a thin film can be manufactured at a low temperature below 250 degrees without lowering film quality. Thus, a device that requires a low temperature process can be reliably and stably manufactured.

Further, since a raw material having low vaporization temperature is used in the method described herein, a low temperature deposition and easy process control is allowed, so that a thin film having good electric and mechanical properties can be obtained. For example, the resulting insulation thin film has good breakdown voltage property, enhanced densification and density, and reduced etching rate.

By using the method described herein, a high quality thin film can be manufactured under various process conditions. That is, a thin film can be formed using a broad range of process temperature and pressure as well as various manufacture methods and apparatuses.

Further, by using the method described herein, thin films having different properties can be manufactured using a single raw material. That is, by adjusting functional groups of raw materials and reaction gases, thin films such as nitride film, carbide film, oxide-nitride film, carbide-nitride film, boride-nitride film, carbide-boride-nitride film as well as silicon oxide film can be manufactured.

Moreover, process margin is increased in the method described herein, so that process control becomes easy and productivity can be drastically improved.

### BRIEF DESCRIPTION OF THE DRAWINGS

FIG. 1A and FIG. 1B are a schematic view showing chemical structures of raw materials according to the present invention.

FIG. 2 is a cross-sectional view of an apparatus for manufacturing a thin film according to an example of the present invention.

FIG. 3 is a flow chart showing the sequence of a method for manufacturing a thin film according to an example of the present invention.

FIG. 4 is a graph of the results from FTIR analysis of silicon oxide films formed using various conditions.

FIG. 5A and FIG. 5B are graphs of the results measuring breakdown voltage of silicon oxide films formed using various conditions.

FIG. 6 is a graph of the results measuring a wet etching rate of silicon nitride films formed using various conditions.

FIG. 7 is graphs of the results from FTIR analysis of silicon nitride films formed using various conditions.

### MODE FOR CARRYING OUT THE INVENTION

Hereinafter, embodiments will be described in detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

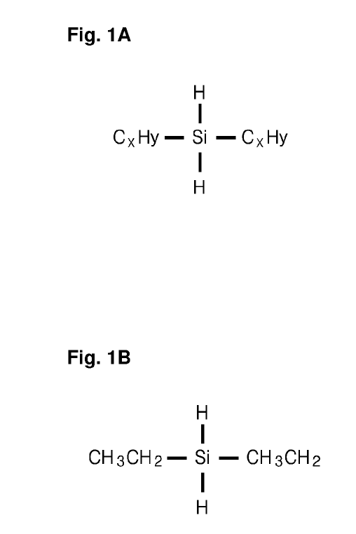

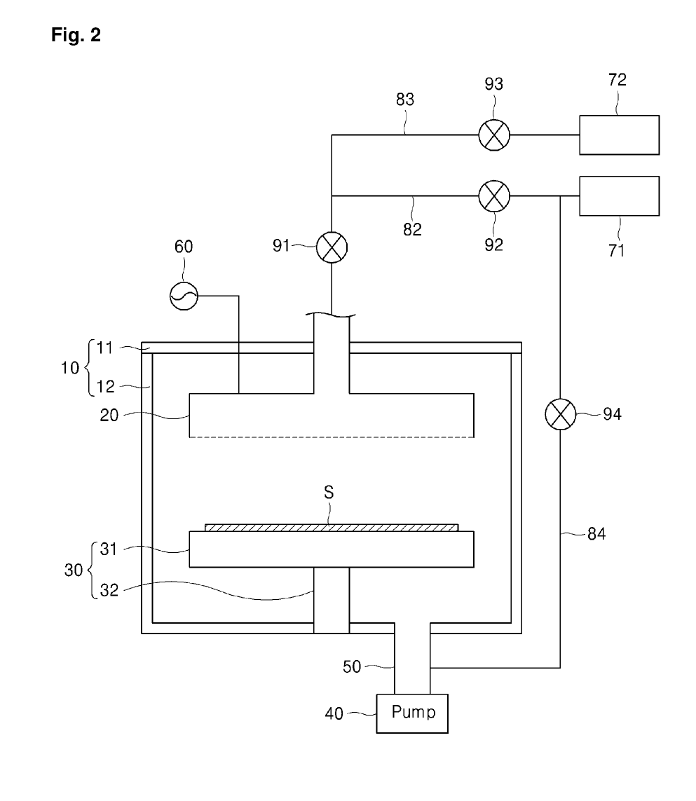

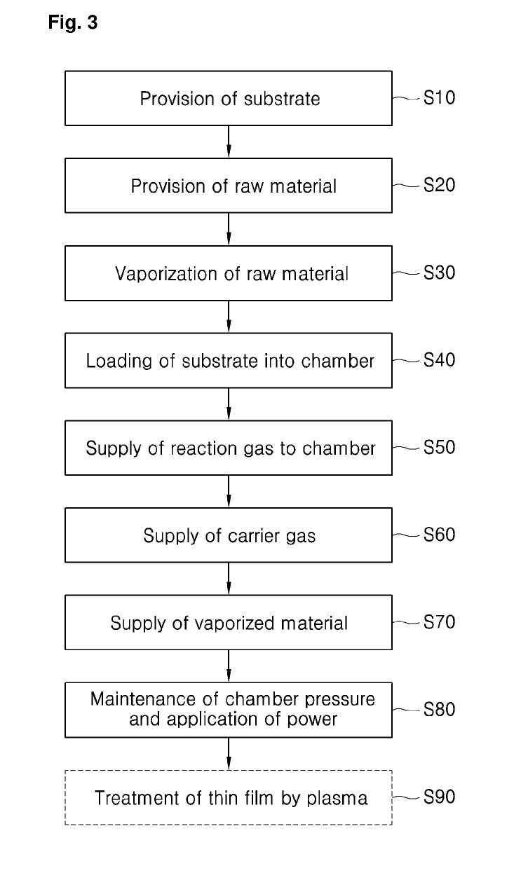

Now, preferred embodiments according to the present invention will be described with reference to the accompanying drawings. FIG. 1A and FIG. 1B area schematic view showing chemical structures of raw materials according to the present invention, FIG. 2 is a cross-sectional view of an apparatus for manufacturing a thin film according to an example of the present invention, and FIG. 3 is a flow chart showing the sequence of a method for manufacturing a thin film according to an example of the present invention. All temperatures indicated below are Celsius degree.

Before an apparatus and a method of manufacturing a thin film are described, a raw material will firstly be described. In an example according to the present invention, a raw material includes an organic silane precursor that is a liquid state at room temperature. The raw material includes a compound which has a basic structure of SiH₂ and functional groups including at least one of carbon, oxygen and nitrogen linearly coupled to both sides of the basic structure. In particular, a compound is used wherein functional groups including carbon and hydrogen are bound to both sides of the basic structure. For example, as a functional group, CxHy (where 1≦x≦9, 4≦y≦20 and y>2x) is bound to the basic structure (see FIG. 1A). The same functional group may be bound to each of both sides, e.g., right and left sides of the basic structure, one functional group may be bound to one side of the basic structure and two functional groups may be bound to another side, or two functional groups may be bound to each of both sides of the basic structure where the functional groups may be the same or different in both sides. Si—H bonding energy in the basic SiH₂ structure is 75 kJ/mol. Depending on functional groups bound to the basic structure, a bond such as Si—O (110 kJ/mol), Si—C (76 kJ/mol), O—C (85.5 kJ/mol), C—H (99 kJ/mol) and N—H (93 kJ/mol) may be formed. The functional group of CxHy forms Si—C bond (76 kJ/mol). Since the bonding energy between silicon and bound functional groups is greater than the bonding energy of Si—H, energy required to decompose a raw material (source) is increased as the number of functional group is increased.

Since the dissociation energy of decomposition is different depending on a functional group, powers having different levels may be applied to generate plasma that is used in manufacturing a thin film. Thus, by adjusting functional groups, raw materials having different dissociation energies and decomposition conditions may be produced. This idea may be adopted for forming a desired thin film. Also, a thin film having desired properties may be manufactured by varying a reaction gas depending on bonds present in a raw material. For example, where two OC₂H₅ groups are bound to SiH₂, a thin film of SiO₂ or SiON may be formed by adjusting a level of power applied or varying a reaction gas (N₂O, O₂, etc.).

Also, in case of an organic silane having CxHy (where 1≦x≦9, 4≦y≦20 and y>2x) as a functional group, a ratio of elements of CxHy functional group may be varied. That is, functional groups such as methyl group (—CH₃), ethyl group (—C₂H₅), benzyl group (—CH₂—C₆H₅), phenyl group (—C₆H₅) may be bound to the basic structure of SiH₂. For example, a compound having a structure wherein CH₃—CH₂ group is linearly bound to the central Si may be used as a raw material (see FIG. 1B). The raw material of C₄H₁₂Si has low vaporization temperature, small molecular weight and high vapor pressure as compared to a conventional TEOS. That is, TEOS has the vaporization temperature of 168 degrees, the molecular weight of 208 and the vapor pressure of 1.2 torr at 20 degrees. In contrast, the C₄H₁₂Si material has the vaporization temperature of 56 degrees, the molecular weight of 88.2 and the vapor pressure of about 208 torr at 20 degrees. Thus, the C₄H₁₂Si material may be vaporized and easily deposited as a thin film at a low temperature. Also, the TEOS source is reacted with a reaction gas after O—C bond (85.5 KJ/mol) is broken due to its structure, while C₄H₁₂Si is reacted with a reaction gas after Si—H bond (75 KJ/mol) is broken. Thus, since C₄H₁₂Si has initial dissociation energy lower than that of TEOS, C₄H₁₂Si is beneficial to deposition at a low temperature.

Now, an apparatus for manufacturing a thin film will be described with reference to FIG. 2. Firstly, the apparatus includes a chamber 10, a substrate-supporting part 30 and a gas injection unit 20. The apparatus also includes a gas-supplying unit for supplying various gases to the gas injection unit 20 and a unit for applying power to the gas injection unit.

The chamber 10 includes a main body 12 with a top portion opened and a top lid 11 configured to open and close and installed in the top portion. When the top lid 11 is coupled to the top portion of the main body 12 to close an interior of the main body 12, a space where a substrate S treatment process such as deposition is performed is formed inside the chamber. Since the space should be typically a vacuum state, an exhaust port is formed in a desired position of the chamber 10 to discharge gas present in the space, and the exhaust port is connected to an exhaust pipe 50 which is connected to an external pump 40 provided outside. Also, a through-hole through which a rotation shaft is inserted is provided in a bottom surface of the main body 12, as will be described below. A gate valve (not shown) is formed in a sidewall of the main body 12 to insert or remove the chamber 10.

The substrate-supporting part 30 is configured to support a substrate and includes a supporting plate 31 and a rotation shaft 32. The supporting plate 31 is a plate of circular shape and horizontally provided inside the chamber 10. The rotation shaft 32 is vertically connected to a bottom surface of the supporting plate 31. The rotation shaft 32 is connected to an external driving unit (not shown) such as motor through the through-hole to elevate and rotate the supporting plate 31. Also, a heater (not shown) is provided in a lower side or interior of the supporting plate 31 to heat the substrate S to a constant process temperature. For example, the substrate may be heated and maintained in the range of 80 to 250 degrees.

Also, the gas injection unit 20 is provided apart from a top portion of the substrate-supporting part 30 and injects process gases such as vaporized raw material, carrier gas, reaction gas, auxiliary gas and so forth toward the substrate-supporting part 30. The gas injection unit 20 is a showerhead-type injection unit and injects different gases introduced from outside and mixed therein toward the substrate S. Of course, in addition to the showerhead-type injection unit, various injection devices such as injector or nozzle may be used.

Also, the gas injection unit 20 is connected to gas-supplying units and gas-supplying lines for supplying various process gases. Firstly, it includes a raw material-supplying unit 71, a raw material-supplying line 82 connected between the raw material-supplying unit 71 and the gas injection unit 20 and a first valve 92 provided on the raw material-supplying line 82 and configured to control supply of a raw material. The raw material-supplying unit 71 includes a reservoir configured to store a liquid raw material, a vaporization device configured to receive and vaporize the liquid raw material and a carrier gas-supplying device configured to store and supply a carrier gas. The vaporization device may be a vaporizer or a bubbler, which will not be described in detail as a general device. A discharge line for discharging the vaporized raw material is connected to a discharge line of the carrier gas-supplying device. These discharge lines are connected to the raw material-supplying line 82. Also, a raw material-discharging line 84 is connected between the raw material-supplying unit 71 and an exhaust pipe 50 of the chamber 10, and a third valve 94 is provided on the raw material-discharging line 84 to control discharge of the raw material. A reaction gas-supplying unit 72 and a reaction gas-supplying line 83 for supplying a reaction gas is connected to the gas injection unit 20, and a second valve 93 is provided on the reaction gas-supplying line 83 to control supply of the reaction gas. The raw material-supplying line 82 and the reaction gas-supplying line 83 are coupled to each other outside the chamber before they are connected to the gas injection unit 20, and a main control valve 91 may be provided on the lines coupled. Of course, the raw material-supplying line 82 and the reaction gas-supplying line 83 may be separately connected to the gas injection unit 20 to supply individual gas.

The apparatus for manufacturing a thin film includes a plasma-generating unit. That is, the plasma-generating unit may be provided to generate plasma inside the chamber and exits various process gases to active species. For example, a power-supplying unit 60 is connected to the gas injection unit 20, and hence, a capacitively coupled plasma (CCP) method may be utilized wherein RF (radio frequency) power is applied to the gas injection unit 20 on a top portion of a substrate in the chamber 10 and the substrate-supporting unit is grounded to exit plasma by RF power in a reaction space for deposition inside the chamber. A method which uses plasma in the manufacture of a thin film has advantages that a reaction gas may easily be activated and deposited at a low temperature, as well as that a high quality thin film may be formed using low energy at a high temperature. In this case, as RF power, at least one of high frequency RF power and low frequency RF power may be used. That is, high frequency RF power and low frequency RF power may be applied to a showerhead alone or in combination. A frequency band of the high frequency RF power is about 3-30 MHz, and a frequency band of the low frequency RF power is about 30-3,000 KHz. For example, high frequency RF power of 13.56 MHz and low frequency RF power of 400 KHz may be used. Also, the high frequency RF power may be used in the range of about 100 to 700 W and the low frequency RF power may be used in the range of 0 to 600 W. Total power of high frequency RF power and low frequency RF power is preferably controlled to 100 to 1,300 W. Preferably, the high frequency RF power may be changed to 100 to 1,000 W, or the low frequency RF power may be changed to 100 to 900 W. Herein, a level of RF power is within a range required to decompose or activate a raw material and a reaction gas.

In addition, when the plasma-generating unit includes a coil, plasma may be generated by inductive coupling. A remote plasma method may be used wherein gases are converted to active species by excitation of plasma outside the chamber 10 or inside the gas injection unit 20 connected to the chamber and the active species are supplied to the substrate. However, various methods using plasma may be applied without any limitation.

When a deposition process is performed by using the apparatus described herein, various process gases are supplied to a top portion of the substrate S through the gas injection unit 20 and plasma is generated inside the chamber 10. Active species are supplied on the substrate and a thin film is formed. The remaining gases and byproducts are discharged outside through the exhaust pipe 50. Of course, the apparatus may be modified in many configurations other than the configuration as described above.

The following description specifically shows an example of a method for manufacturing a thin film with reference to FIG. 3. A method for manufacturing a thin film includes the steps of providing a substrate, providing a raw material, vaporizing the raw material and loading the substrate into a chamber, and supplying the vaporized raw material to an interior of the chamber.

Firstly, a substrate S is provided (S10). As the substrate S, for example, a silicon wafer may be used, and if necessary, a substrate made from various materials may be used.

Then, a raw material is provided (S20). The raw material includes an organic silane precursor that is a liquid state at room temperature. The raw material has been previously described and overlapped descriptions are omitted. A precursor compound which has a basic structure of SiH₂ and functional groups including carbon and hydrogen linearly coupled to both sides of the basic structure is selected as the raw material. In particular, a precursor, i.e., C₄H₁₂Si wherein ethyl functional group (—C₂H₅) is bound to SiH₂ is selected.

The raw material selected depending on a desired thin film is vaporized (S20). That is, the raw material present as liquid at room temperature is converted to a gaseous state before it is introduced into a chamber. The raw material is converted to gas using a vaporization apparatus such as vaporizer or bubbler known in the art. When a bubbler is used, a liquid raw material may be bubbled using gas such as argon (Ar), hydrogen (H2), oxygen (O2), nitrogen (N2), helium (He) and the like.

After or during the raw material is vaporized, a substrate is loaded into a chamber (S40). That is, the substrate S, e.g., a silicon wafer is mounted on a substrate-supporting part in the chamber. A single substrate or a plurality of substrates S may be mounted on the substrate-supporting part. A heater is provided in the substrate-supporting part and the substrate may be heated to an appropriate temperature. After the substrate S is mounted on the substrate-supporting part, vacuum pressure is adjusted to a desired level, and a temperature of the substrate S is controlled by heating the substrate-supporting part. A process temperature is controlled in the range of 80 to 250 degrees. If the process temperature is less than 80 degrees, particles are produced while a thin film is formed so quality of the film is lowered. If the temperature is greater than 250 degrees, it may adversely affect subsequent processes.

Then, the substrate is exposed to various gases (S50-S70). That is, a vaporized raw material and a reaction gas are introduced into a chamber. The vaporized raw material includes elements constituting main components of a thin film, and the reaction gas is reacted with the raw material to form the thin film. For example, when a silicon oxide thin film is formed, a material including silicon (e.g., C₄H₁₂Si) is used as the raw material and oxygen-containing gas such as oxygen or ozone is used as the reaction gas. The raw material and the reaction gas may be concurrently introduced, or either one may be firstly introduced. For example, after the reaction gas is introduced into the chamber (S50), the vaporized raw material may be introduced (S70). The vaporized raw material may preferably be supplied together with a carrier gas (S60). The carrier gas may be introduced before the raw material is introduced, or the carrier gas may be introduced concurrently to the raw material. The carrier gas allows smooth flow and accurate control of the gaseous raw material. The carrier gas is preferably an inert gas which does not affect the raw material. For example, the carrier gas includes at least one selected from helium, nitrogen and argon. The reaction gas is selected depending on properties of the resulting thin film, and in this embodiment, includes at least one selected from oxygen-containing gas, nitrogen-containing gas, hydrocarbon compound (CxHy, 1≦x≦9, 4≦y≦20, y>2x), boron-containing gas and silicon-containing gas. In addition to the reaction gas, an auxiliary gas may be additionally used to promote the formation of a thin film. Of course, the use and type of auxiliary gas may be determined depending on a thin film to be formed and a reaction gas.

Now, the introduction of various process gases will be detailed described. Firstly, a reaction gas, for example oxygen is supplied through the reaction gas-supplying unit 72 and the reaction gas-supplying line 83. Once oxygen is introduced into the chamber through the gas injection unit 20, a carrier gas (e.g., helium) and the vaporized C₄H₁₂Si raw material is flowed into the exhaust pipe 50 through the raw material-discharging line 84 and the third valve 94. Thereby, gas flow may be stabilized before the vaporized C₄H₁₂Si material is introduce into the chamber 10. That is, it is to introduce gases into the chamber 10 after flow fluctuation due to initial flow of C₄H₁₂Si material and carrier gas is discharged through the exhaust pipe and gas flow is stabilized. After the flow of C₄H₁₂Si raw material and carrier gas is stabilized, the third valve 94 is switched to OFF and the first valve 92 is switched to ON, and the C₄H₁₂Si material and the carrier gas are injected on the substrate through the gas injection unit 20. Thus, the reaction gas oxygen, the vaporized C4H12Si raw material and the carrier gas are mixed in the gas injection unit 20 and injected on the substrate S.

Once these process gases are introduced into the chamber 10 and a desired pressure is maintained inside the chamber, RF power is applied to the gas injection unit 20, i.e., the showerhead (S80). A method which uses plasma in the manufacture of a thin film has advantages that a reaction gas may easily be activated and deposited at a low temperature, as well as that a high quality thin film may be formed using low energy at a high temperature. A process pressure is preferably maintained in the range of 1 to 10 torr. If the process pressure is less than 1 torr, a deposition rate on the substrate is too low and productivity is decreased. If the pressure is greater than 10 torr, a deposition rate is too high to obtain a dense film. Once the process gases are introduced and plasma is generated, the gases are converted to active species. These active species are moved on the substrate and the reaction gas oxygen is reacted with silicon present in C₄H₁₂Si to form a thin film. The power and pressure is maintained for a desired period until a thin film having a desired thickness is formed. Even if the resulting thin film was formed at a low temperature, since the raw material is fully reacted with the reaction gas to form the thin film, the film has good breakdown voltage and wet etching rate. The process temperature, pressure, gas flow rate, applied power level and the like may be varied depending on a method and an apparatus of manufacturing a thin film.

A thin film having denser structure and good electrical properties may be manufactured by varying voltage applied, flow rates of gases supplied and so forth during manufacturing a thin film. When a thin film is formed at a low temperature below 250 degrees, a thin film is grown at a low temperature, and hence the whole properties of the thin film may be unstable. To solve such instability, the whole properties may be controlled by generating a difference in density between a film initially deposited at an interface with the substrate and a surface of the film grown to a desired thickness. Also, by generating a difference in density of a film in a thickness direction, properties such as breakdown voltage and wet etching rate may be accurately controlled. That is, the film density may be controlled in a thickness direction of a thin film to be formed by increasing, decreasing, or increasing and then decreasing voltage applied or flow rate of a raw material during a deposition process. For example, a thin film may be formed by gradually increasing the total RF power of applied voltage from 100 to 1,300 W under a constant flow rate of raw material. Also, a thin film may be formed by gradually increasing the flow rate of raw material from 50 sccm to 700 sccm and then decreasing to 50 sccm under a constant power to generate plasma during a deposition process. Furthermore, the flow rate of raw material is increased from 50 sccm to 700 sccm during a deposition process. The process may be performed by increasing applied power from 100 W to 1,300 W together with the increase of the raw material flow rate. A range of the applied power includes a range spanned over minimum and maximum powers required to decompose or activate the raw material and the reaction gas. A range of the raw material flow rate includes a range spanned over minimum and maximum amounts of the raw material that can be formed as a thin film alone or by a reaction with other reaction gases in the chamber.

After the formation of a thin film is terminated, the resulting thin film may be treated by plasma (S90). That is, after a thin film is manufactured, a surface of the thin film is treated by plasma for a desired period by generating oxygen or N₂O plasma to remove unreacted bonds or particles residue in the surface of the film. After all processes are completed, the substrate is unloaded outside the chamber and the substrate is transferred to a subsequent process.

Although a PECVD process has been described, a thin film may be manufactured using various methods or apparatuses. That is, a thin film may be manufactured by deposition methods such as SACVD (sub-atmospheric CVD), RACVD (radical assisted CVD), RPCVD (remote plasma CVD), ALD, or the like. In SACVD, deposition is carried out while maintaining the process pressure in the range of 200 to 700 torr that is slight lower than atmospheric pressure and gases are injected similarly to said process. That is, a raw material and reaction gases are introduced into the chamber via a gas injection port, and then a thin film is deposited under high pressure. A RPCVD process generates plasma outside a chamber, i.e., a remote location apart from the chamber and supplies active species to an interior of the chamber, and RACVD generates plasma within a showerhead coupled to a chamber and provides active species on a substrate. In RACVD or RPCVD, after gas is activated by remote plasma and introduced into a chamber, a deposition process is carried out. Thus, they also have an advantage that damage to a substrate may be minimized. In an atomic layer deposition (ALD) method, process gases are separately provided and a thin film is formed by surface saturation of the process gases. That is, a source gas is supplied inside a chamber and reacted with a surface of a substrate to chemically deposit a single atomic layer on the surface of the substrate. Then, a purge gas is supplied to remove the remaining or physically absorbed source gas by the purge gas. Then, a reaction gas is supplied on a top of the first single atomic layer and the reaction gas is reacted with the source gas to grow a second layer. Then, the purge gas is supplied to remove the reaction gas that is not reacted with the first layer. These processes are repeated to form a thin film.

Now, the manufacture of a silicon oxide film and the quality of the resulting thin film will be described. Since the manufacture of a silicon oxide film is performed according to the process described above, overlapped descriptions are omitted.

Firstly, a silicon wafer is transferred into the chamber and placed on the substrate-supporting part which is maintained at a temperature of 100-150 degrees. Then, the chamber is pumped to maintain a vacuum state inside the chamber. A vacuum pressure is about 5 torr. While controlling the process temperature as described above, 5000 sccm of oxygen (O₂) as a reaction gas is introduced into the chamber through the gas injection unit, i.e., a showerhead. A pressure inside the chamber is maintained at about 5 torr and a temperature of the showerhead is consistently maintained. For example, the temperature of the showerhead may be controlled by circulating a fluid maintained at 85 degrees in the showerhead. In this case, since the deposition of a thin film is performed at a low temperature, if the temperature of the showerhead is less than 60 degrees, contaminants may be generated. To prevent the generation of contaminants, the temperature of the showerhead should be consistently maintained.

While introducing the reaction gas oxygen in the chamber through the showerhead at the flow rate of 5,000 sccm, helium as a carrier gas is flowed at 4,500 sccm. Then, C₄H₁₂Si that is vaporized in a vaporization device which is maintained at a temperature above 60 degrees is flowed into the exhaust pipe through the discharge line and the third valve at 200 sccm. Until the C₄H₁₂Si flow rate of 200 sccm is stabilized without any flow fluctuation, that is, the flow of raw material gas is stabilized, the raw material gas is flowed into the exhaust pipe for about 15 seconds. Once the flow of C₄H₁₂Si is stabilized, the valve is switched to flow the gas through the showerhead.

The reaction gas oxygen 5,000 sccm, the carrier gas helium 4,500 sccm and the vaporized C₄H₁₂Si 200 sccm are mixed in the showerhead and introduced into the chamber. RF power is applied to this showerhead to generate plasma in the chamber. In this case, high frequency RF power 800 W and low frequency RF power 300 W are applied as the RF power to generate plasma. The gases are activated by applied RF power and reacted with each other on the substrate to deposit a thin film. After this condition is maintained for a desired period until a thin film having a desired thickness is formed, the deposition process is terminated. After the deposition is terminated, a surface of the thin film is treated by oxygen or N₂O plasma for about 5 seconds to remove unreacted bonds or particles, and unreacted or residual gases are purged using He or O₂ gas outside the chamber. After all processes are completed, the substrate is transferred outside the chamber.

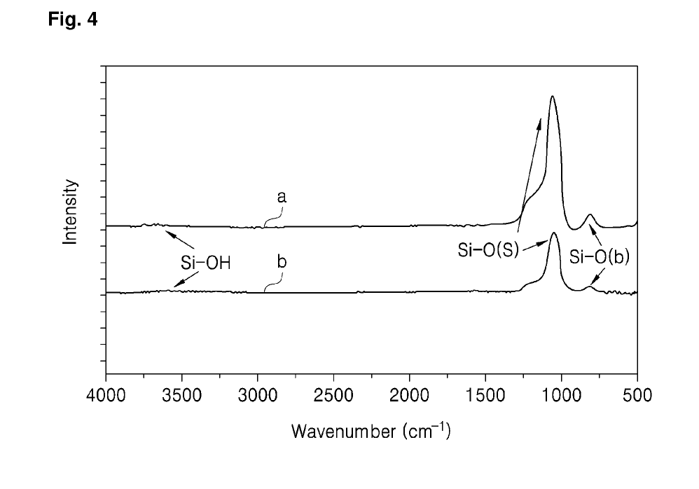

The quality of the silicon oxide film thus formed was evaluated. FIG. 4 is a graph of the results from FTIR (Fourier transform infrared spectroscopy) analysis of silicon oxide films formed using various conditions. In FIG. 4, (a) represents a conventional silicon oxide film manufactured using TEOS at the process temperature of 350 degrees, and (b) represents a silicon oxide film manufactured using C₄H₁₂Si at the process temperature of 150 degrees. As can be seen from FIG. 4, the oxide film formed at a low temperature according to this example was confirmed as a silicon oxide film having stable bonds with a similar bonding structure as compared to FTIR spectrum on an oxide film formed at a high temperature even though it was deposited at relatively low temperature relative to the TEOS process. Also, it was demonstrated that a few hydrogens are present in the thin film in the light of very week strength of peaks such as Si—H and Si—OH.

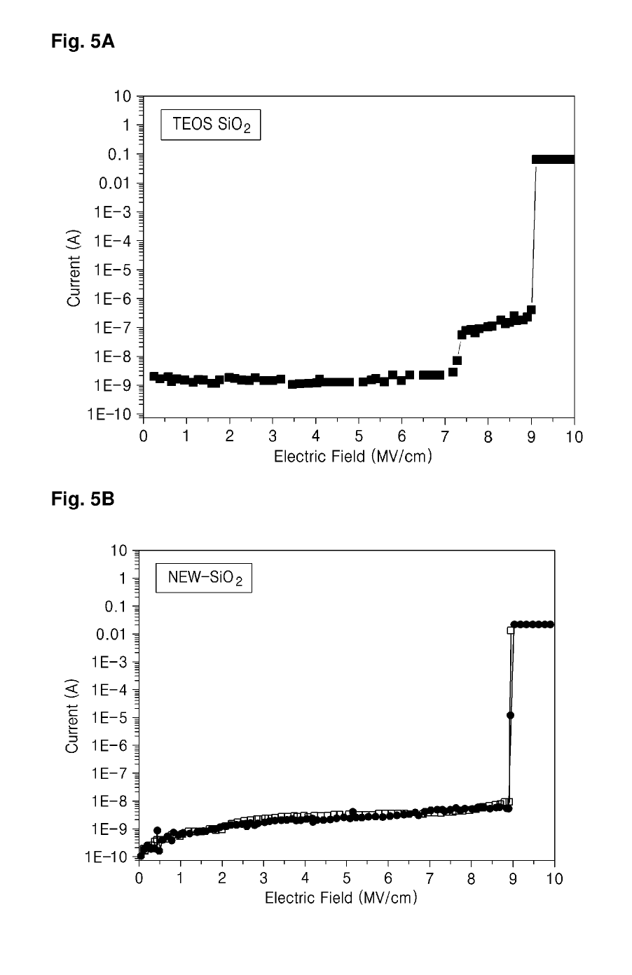

Also, voltage was applied to the oxide film formed in this example to measure a breakdown voltage. FIG. 5A and FIG. 5B are graphs of the results measuring breakdown voltage of silicon oxide films formed using various conditions. FIG. 5A is a group of the result from a conventional silicon oxide film manufactured using TEOS at the process temperature of 350 degrees, and FIG. 5B is a group of the results from silicon oxide films manufactured using C₄H₁₂Si at the process temperature of 150 degrees. As can be seen from FIG. 5A and FIG. 5B, all of two oxide films had breakdown voltage of 9 MV/cm or higher and showed good breakdown property. In particular, the silicon oxide film formed using C₄H₁₂Si showed stable voltage property without current leakage and the breakdown was started when it was greater than 9 MV/cm.

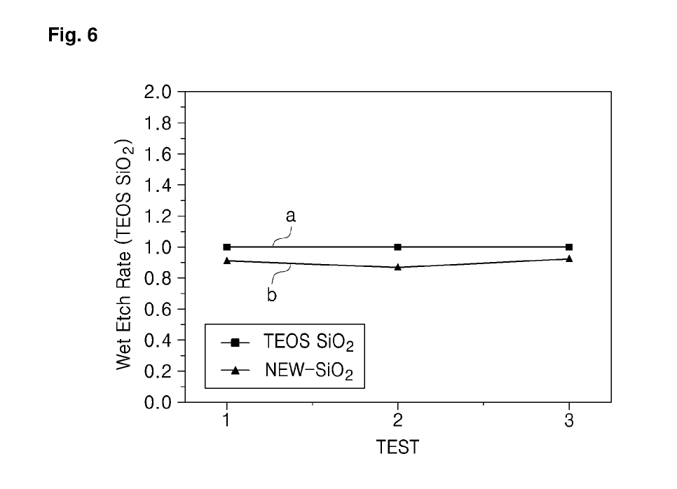

The formed oxide film was wet etched using a HF solution and a result was measured. That is, a dilute solution was manufactured by mixing pure water with HF at a ratio of 200:1 pure water:HF. A plurality of wafers having a silicon oxide film deposited was dipped in the dilute solution to etch the film, and an etching rate was measured. FIG. 6 is a graph of the results measuring a wet etching rate of silicon nitride films formed using various conditions. In FIG. 6, (a) represents a conventional silicon oxide film manufactured using TEOS at the process temperature of 350 degrees, and (b) represents a group of a silicon oxide film manufactured using C₄H₁₂Si at the process temperature of 150 degrees. The etching rate is represented as a relative etching rate of the oxide film according to this example relative to the etching rate of 1 represented for the TEOS-oxide film. As can be seen from FIG. 6, the oxide film according to this example has a lower etching rate than the conventional oxide film and shows good etching property.

From the results described above, it was demonstrated that the silicon oxide film according to this example is formed as a dense thin film having good electrical and mechanical properties even if it was deposited at a low temperature. Generally, where a thin film is formed at a low temperature, since raw materials are less decomposed relative to a high temperature process, a large amount of hydrogens may be contained in the resulting thin film and many hydrogen bonds may be present in the thin film. Since the hydrogen bond is hydrophilicity, a wet etching rate is increased. The wet etching rate is largely related to densification of the film, i.e., density. That is, a high wet etching rate represents a less dense film. Also, when hydrogens are present in the thin film, they are replaced or coupled by/to other atoms so an electrical deficiency may be produced. According to this example, it can be seen that even if a thin film is formed at a low temperature, the thin film has good breakdown voltage and wet etching property. The reason is that the raw material C₄H₁₂Si has low vaporization temperature and low dissociation energy. That is, bonds between elements in C₄H₁₂Si raw material are easily broken and these elements are actively reacted with a reaction gas, so that hydrogen bond is little generated in the resulting thin film as a byproduct after reactions are completed. Since hydrogen bond is little contained in the thin film, various properties of the thin film are improved. Further, since the reactivity of the raw material with the reaction gas is high, the property of pure silicon oxide film can be obtained even at a low temperature.

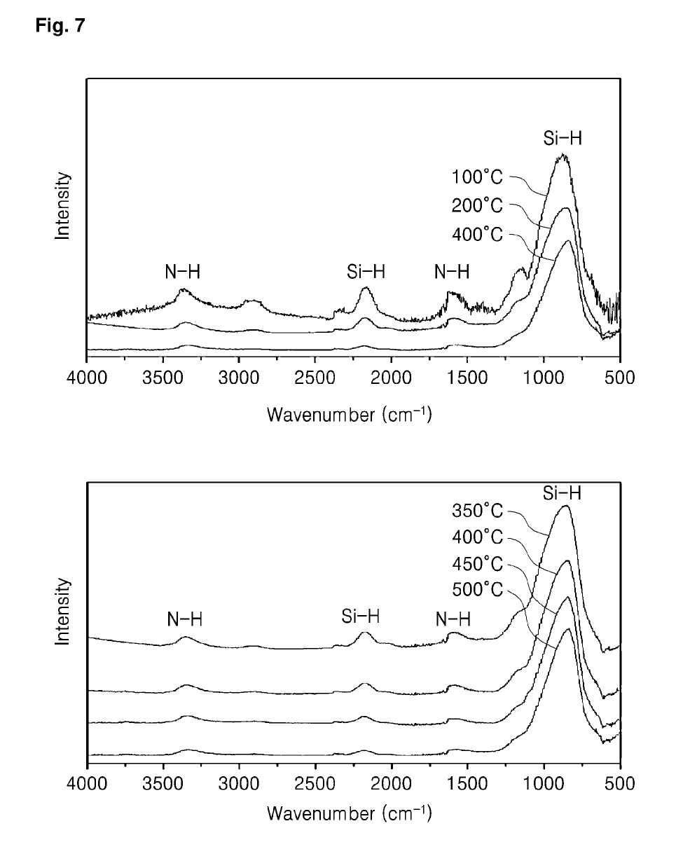

Although the silicon oxide film manufactured using C₄H₁₂Si as a raw material and oxygen as a reaction gas was exemplified in this example, various thin films may be manufactured by varying the reaction gas. For example, a silicon nitride film may be formed by the same procedure as described above using a nitrogen-containing gas such as nitrogen (N2), ammonia (NH₃) and so forth. That is, the silicon nitride film may be formed by a reaction between silicon present in C₄H₁₂Si and nitrogen present in the reaction gas. A silicon nitride oxide formed using nitrogen (N₂) and ammonia (NH₃) gases as a reaction gas at a varied process temperature of 100 to 500 degrees was evaluated. FIG. 7 is graphs of the results from FTIR analysis of silicon nitride films formed using various conditions. As can be seen from FIG. 7, silicon nitride films with stable bonds between elements were formed in the board range of process temperature.

Although the present invention has been described with reference to the specific embodiments, it is not limited thereto. Therefore, it will be readily understood by those skilled in the art that various modifications and changes can be made thereto without departing from the spirit and scope of the present invention defined by the appended claims and equivalents thereof.

1. A method of manufacturing a thin film, comprising:
providing a substrate;
providing a raw material comprising an organic silane having CxHy (where 1≦x≦9, 4≦y≦20 and y>2x) as a functional group;
vaporizing the raw material;
loading the substrate into a chamber;
supplying the vaporized raw material to an interior of the chamber; and
wherein a reaction gas is supplied to the chamber before the vaporized raw material is supplied.

2. The method of manufacturing a thin film according to claim 1, wherein the raw material comprises C₄H₁₂Si.

3. The method of manufacturing a thin film according to claim 2, wherein the functional group comprises at least one selected from a methyl group (—CH₃), an ethyl group (—C₂H₅), a benzyl group (—CH₂—C₆H₅) or a phenyl group (—C₆H₅).

4. The method of manufacturing a thin film according to claim 2, wherein the reaction gas is reacted with the raw material to form a thin film, the reaction gas comprising an oxygen-containing gas.

5. The method of manufacturing a thin film according to claim 2, wherein the vaporized raw material is supplied together with a carrier gas comprises at least one selected from helium, argon or nitrogen.

6. The method of manufacturing a thin film according to claim 5, wherein the thin film formed on the substrate is an insulation film containing silicon.

7. The method of manufacturing a thin film according to claim 5, wherein after the vaporized raw material is supplied, plasma is generated in the chamber.

8. The method of manufacturing a thin film according to claim 7, wherein the high frequency RF power is changed to a range of 100 W to 1,000 W and the low frequency RF power is changed to a range of 100 W to 900 W for deposition of the thin film.

9. The method of manufacturing a thin film according to claim 8, wherein a flow rate of the vaporized raw material is changed in a range of 50 to 700 sccm during deposition of the thin film.

10. The method of manufacturing a thin film according to claim 9, wherein the thin film is deposited by increasing and then decreasing the flow rate while consistently maintaining the RF power, or by increasing the flow rate and the RF power.

11. A method of manufacturing a thin film, comprising:
providing a substrate;
providing a raw material comprising a compound which has a basic structure of SiH₂ and functional groups comprising carbon and hydrogen linearly coupled to both sides of the basic structure;
vaporizing the raw material;
loading the substrate into a chamber;
supplying the vaporized raw material to an interior of the chamber; and
wherein a reaction gas is supplied to the chamber before the vaporized raw material is supplied.

12. The method of manufacturing a thin film according to claim 11, wherein the raw material comprises C₄H₁₂Si.

13. The method of manufacturing a thin film according to claim 12, wherein the functional group comprises at least one selected from a methyl group (—CH₃), an ethyl group (—C₂H₅), a benzyl group (—CH₂—C₆H₅) or a phenyl group (—C₆H₅).

14. The method of manufacturing a thin film according to claim 12, wherein the reaction gas is reacted with the raw material to form a thin film, the reaction gas comprising an oxygen-containing gas.

15. The method of manufacturing a thin film according to claim 12, wherein the vaporized raw material is supplied together with a carrier gas comprises at least one selected from helium, argon or nitrogen.

16. The method of manufacturing a thin film according to claim 15, wherein the thin film formed on the substrate is an insulation film containing silicon.

17. The method of manufacturing a thin film according to claim 15, wherein after the vaporized raw material is supplied, plasma is generated in the chamber.

18. The method of manufacturing a thin film according to claim 17, wherein the high frequency RF power is changed to a range of 100 W to 1,000 W and the low frequency RF power is changed to a range of 100 W to 900 W for deposition of the thin film.

19. The method of manufacturing a thin film according to claim 18, wherein a flow rate of the vaporized raw material is changed in a range of 50 to 700 sccm during deposition of the thin film.

20. The method of manufacturing a thin film according to claim 19, wherein the thin film is deposited by increasing and then decreasing the flow rate while consistently maintaining the RF power, or by increasing the flow rate and the RF power.
